(19) United States
(12) Patent Application Publication
(10) Pub. No.: US 2012/0132257 A1
(43) Pub. Date: May 31, 2012

(54) Solar Electricity and Heat Transfer Systems

(76) Inventor: Jeffrey D. Combelic, Boulder, CO (US)

(21) Appl. No.: 13/306,810

(22) Filed: Nov. 29, 2011

Related U.S. Application Data
(60) Provisional application No. 61/417,584, filed on Nov. 29, 2010.

(51) Int. Cl. H01L 31/058

(52) U.S. Cl. 136/248

(57) ABSTRACT

A solar electricity and heating system comprises at least one photovoltaic panel mountable above a sloped roof surface for providing photovoltaic electricity and providing heating a space between the panel and the roof surface. A heat conduction collector is positioned in the space between the panel and the roof surface for collecting air warmed by the panel. A closure system is mounted to at least two sides of the photovoltaic system for partially enclosing the space, which produces a chimney effect for the air heated by the panel. A liquid heat transfer system may be coupled to the collector for thermally coupling the collector to at least one of a heat storage system and a heat circulation system. A thermostat-activated pump may be provided for circulating liquid through the heat transfer system.

### CROSS-REFERENCE TO RELATED APPLICATION

This application claims priority to Provisional Patent Application Ser. No. 61/417,584, filed Nov. 29, 2010.

### FIELD OF INVENTION

This invention relates generally to building structures, and more particularly, to a roof structure employed in building designs to provide photovoltaic electricity and solar heating.

### BACKGROUND OF THE INVENTION

In home construction, such as in the construction of custom and track single-family dwellings, a conventional home has a Home Energy Rating (HERS) of 100. However, a home may be designed to include passive and active solar energy systems and/or other renewable energy systems such that the structure's HERS rating is zero. A so-called Zero-Energy Home generates enough power so that the home has no utility bill. In some cases, a dwelling may produce more energy than it consumes. This excess energy may be used to charge a plug-in hybrid car. In a sunny climate, a Photovoltaic (PV) array on the roof would provide electrical power. In a windy climate, a wind-power generator may supplement or replace the PV array. A solar thermal system may be used to provide home heating and/or hot water. This novel home style is called a Hybrid Home.

As the popularity increases for passive and active solar systems to service the energy needs for homes and other buildings, new homes are being built and existing homes are being retrofitted to incorporate these new systems. Many solar energy designs incorporate both solar panels for generating electricity and a south-facing passive solar space for heating the building.

The power generated by a photovoltaic device is proportional to the illumination incident thereon. Solar panels are usually affixed to a south facing roof (or north in the southern hemisphere). The optimal angle (or pitch) of the roof depends on a number of factors, including the latitude of the location where the building is constructed. If relatively large amounts of power are to be generated, fairly large collection areas are required. The collection area depends on a number of factors, such as electricity needs of the building, angular orientation of the building relative to South, the pitch of the roof, shading due to other structures or trees, and the local climate (e.g., average cloud cover). In some designs, photovoltaic devices may be affixed to roofs that have an east/west pitch. Thus, the design of a roof structure for providing photovoltaic electricity generation needs to be customizable relative to the building's features and the site. Similarly, the passive solar space design is typically based on a number of factors, including the heating requirements for the building, the building's angular orientation relative to South, shading, and pre-existing architectural features. Thus, a roof structure for a building that incorporates a passive solar space should be customizable.

There is a need in the art for a roof system that facilitates building designs that incorporate photovoltaic electricity and passive solar heating systems.

### SUMMARY

The present invention solves these and other needs. However, aspects of the invention are not limited to the benefits, advantages, and features disclosed herein. Rather, those skilled in the art will appreciate that aspects of the invention may provide additional benefits and advantages, and alternative aspects of the invention may include additional features.

In accordance with an aspect of the invention, a solar electricity and heating system comprises at least one photovoltaic panel mountable above a sloped roof surface for providing photovoltaic electricity and providing heating a space between the panel and the roof surface. A heat conduction collector is positioned in the space between the panel and the roof surface for collecting air warmed by the panel. A closure system is mounted to at least two sides of the photovoltaic system for partially enclosing the space, which produces a chimney effect for the air heated by the panel. A liquid heat transfer system may be coupled to the collector for thermally coupling the collector to at least one of a heat storage system and a heat circulation system. A thermostat-activated pump may be provided for circulating liquid through the heat transfer system.

In accordance with another aspect of the invention, a modular roof system comprises multiple trusses, wherein each truss comprises a horizontal chord (e.g., a ceiling joist) that is configured to be coupled to a pre-existing structure. The horizontal chord has a length calculated to accommodate a passive solar space. Each truss also comprises a primary roof chord (e.g., a roof joist) coupled to the horizontal chord. The primary roof chord has a length and pitch calculated to provide sufficient surface area to the roof system to accommodate a solar photovoltaic system capable of providing all of the structure's electricity usage and heating needs. The truss is engineered per climatic snow and wind conditions. In some aspects, the truss comprises a mid span bearing point, which is incorporated in the house design. The pitch of the truss may be designed to provide an attic or living space.

According to another aspect of the invention, a method for constructing a modular roof system comprises constructing a plurality of horizontal truss members, each truss member having a length designed to cover a pre-existing structure plus a passive solar space addition; and constructing a primary roof having a pitch and a surface area designed to accommodate a solar photovoltaic system to provide all of the structure's electricity usage and heating needs.

Another aspect of the invention provides for a software program residing on a computer-readable memory. The software program comprises a truss design code segment configured for calculating a roof system width designed to cover a pre-existing structure plus a passive solar space addition; and a roof surface code segment configured for calculating roof surface area and pitch sufficient to accommodate a solar photovoltaic system to provide all of the structure's electricity usage.

In yet another aspect of the invention, a solar heating system comprises a heat conduction collector mountable to an upper section of a passive solar space; a liquid heat transfer system comprising at least one conduit for thermally coupling the heat conduction collector to a thermal mass used for heating a structure; and a pump configured for circulating liquid through the heat transfer system. The pump may be controlled by a differential temperature controller or a cooling thermostat.

Aspects of the invention may be combined with recognized energy efficient methods of construction. Such aspects may incorporated into remodels, such as pop-tops (second story additions), as well as new homes. For example, aspects of the invention may be included in a building design comprising a superior insulation package, a grid-tie photovoltaic system mounted on the roof, a Passive Solar Space (PSS), a heat distribution system (such as a forced air system) for moving hot air from the PSS throughout the house, and a thermal mass to retain the distributed heat.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a schematic diagram depicting a structure configured in accordance with certain aspects of the present disclosure;

FIG. 2 is a cross-sectional diagram of a combined solar electricity and heating system configured in accordance with one aspect of the disclosure;

FIG. 3 is a cross-sectional diagram of a combined solar electricity and heating system depicting several aspects of the disclosure; and

FIG. 4 is a block diagram of heating system configured according to an aspect of the disclosure.

### DETAILED DESCRIPTION

In the description which follows, like parts are marked throughout the specification and drawings with the same respective reference numerals. The drawings are not necessarily to scale and in some instances proportions may have been exaggerated in order to more clearly depict certain features of the invention.

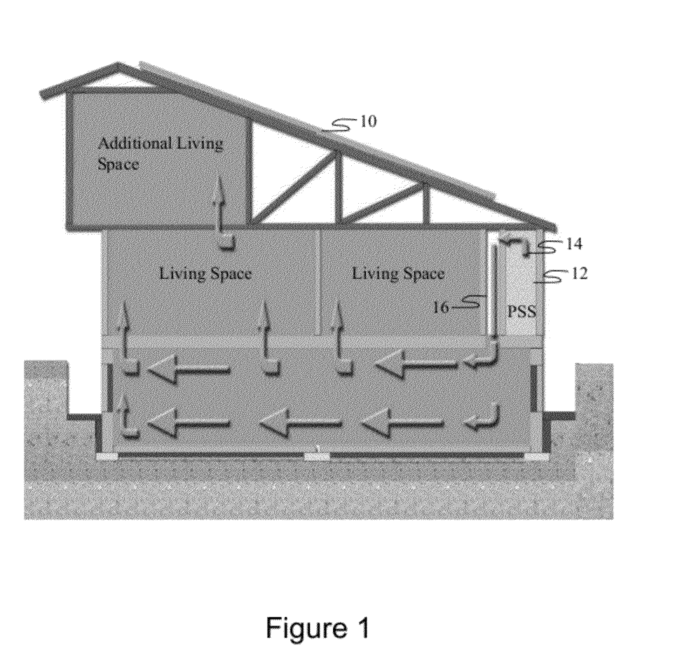

Aspects of the invention may be understood with reference to a structure configured with a PV system and a solar thermal system, such as depicted in FIG. 1. The structure comprises a PV array 10 on a south-facing roof and a passive solar space (PSS) 12. In a typical solar thermal system, heated air 14 from the PSS 12 is distributed throughout the structure's living space by a forced-air ventilation system 16.

The structure comprises a passive solar space, such as PSS 12, which is an enclosed area of the structure that is adjacent to the structure's living space. The PSS 12 provides indirect solar gain wherein sunlight enters the structure through exterior windows. In one aspect of the invention, heat from the PSS 12 is captured and stored in a thermal mass, such as a masonry wall and/or concrete floors. The heat is then slowly transmitted throughout the structure via conduction and convection. Similarly, heat collected from the PSS 12 may be transferred to the living space using a fluid (such as water) or by air using natural convection or forced convection.

Many factors that influence the design of the PSS 12 also influence the design of the roof system, including the truss design. The 47-degree difference in the altitude of the sun at solar noon between winter and summer can be an important factor in passive solar design. This information is combined with local climatic data (which indicates heating and cooling requirements) to determine at what time of the year solar gain will be beneficial for thermal comfort, and when it should be blocked with shading. Since overhangs prevent solar gain during the summer, an aspect of the invention provides for a truss design that is adaptable to the specific shading requirements of the structure.

The design of the PSS 12, including the overhang of the roof system, can also be influenced by other factors, such as solar insulation (i.e., the measure of solar radiation energy received on a given surface area in a given time); micro-climate details relating to breezes, humidity, vegetation, and land contours; obstructions and shadowing; locations of room types and interior walls and doors; angular orientation of the structure relative to the equator; and the glass area of the structure. Aspects of the invention provide designing the roof system and trusses in accordance with the aforementioned design considerations, as well as others.

Passive solar building design is often a foundational element of a cost-effective zero energy building (ZEB). However, a ZEB is usually not purely passive, having active mechanical renewable energy generation systems, such as photovoltaics, which generate electrical power by converting solar radiation into direct current electricity using semiconductors that exhibit the photovoltaic effect. Photovoltaic power generation often employs solar panels 10 comprising a number of cells containing a photovoltaic material. In some aspects of the invention, the roof system is designed to provide a surface area that accommodates the design of a ZEB. In such aspects of the invention, the pitch of the roof system may be configured with respect to any number of parameters in order to provide the surface area necessary to support the number of solar panels in a ZEB design.

In other aspects of the invention, the roof system may be configured to comprise Building-integrated photovoltaics (BIPV), which are photovoltaic materials used in place of conventional building materials in parts of the building envelope, such as the roof, skylights, or facades. The roof system is designed to provide a roof system with a sufficient surface area for the BIPV such that the BIPV serve as the principal source of electrical power for the structure.

According to an aspect of the invention, a truss may be designed so as the roof system incorporates a living space (such as the additional living space shown in FIG. 1) and/or an attic space. Cross bracing is provided for structural support and may be adapted relative various parameters, such as load-bearing requirements for the roof system and length of the ceiling joists.

In accordance with aspects of the invention, a photovoltaic energy system is configured for generating both electricity and useful heat from sunlight. Since silicon photovoltaic cells typically convert only 15-17% of the received solar radiation, much of the sunlight absorbed by the cells is converted to heat.

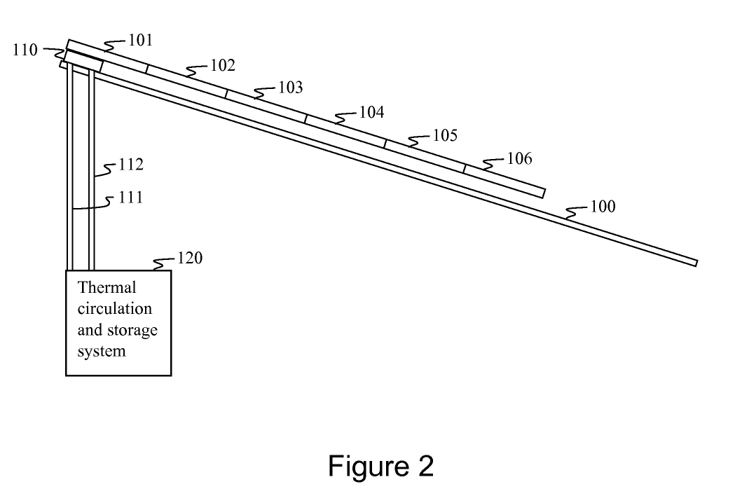

FIG. 2 is a cross-sectional diagram of a combined solar electricity and heating system configured in accordance with one aspect of the invention. A plurality of photovoltaic cells 101-106 are placed above a sloped roof surface 100 of a structure, such as a dwelling. Sunlight incident upon the cells 101-106 is converted to electricity. However, much of the sunlight is absorbed by the cells 101-106, which causes the cells to radiate heat. Since the cells 101-106 are typically installed above the roof surface 100, the space between the surface 100 and the cells 101-106 heats up, thereby providing a heat collection space. Near the top of the photovoltaic array 101-106, the heated air is thermally coupled to a heat-conduction collector 110, such as a fin tube that provides a channel for a fluid circulated throughout a thermal circulation and storage system 120. In one aspect of the invention, a glycol solution is pumped throughout the system 120, entering the collector 110 via an entry tube 111 and exiting the collector 110 via an exit tube 112. Heat collected by the collector 110 may be stored and/or circulated throughout the structure's interior by the thermal circulation and storage system 120. For example, heat may be stored in a thermal mass, such as a concrete floor system. In some aspects of the invention, the collected heat may be employed for providing hot water, such as in a conventional hot-water heater.

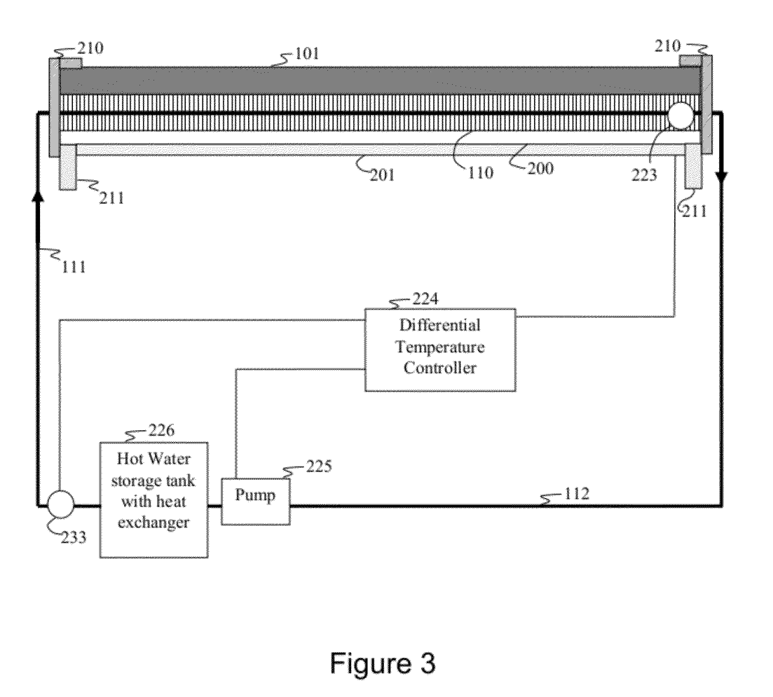

FIG. 3 is a cross-sectional diagram of a combined solar electricity and heating system configured in accordance with an aspect of the invention. The cross section is the top of the photovoltaic array 101-106 (i.e., the top of cell 101) in the vicinity of the collector 110 shown in FIG. 2. The collector (e.g., a fin tube) 110 occupies the space between the cell 101 and the roof's surface, which may comprise shingles 200 on top of roof sheathing 201. The thermal energy from the heated air is collected at the fin tube 110 by a glycol solution, which is circulated through a heat-exchanger loop in a solar storage tank 226.

Side closure flashing 210 is attached to the sides of the array (such as shown with respect to cell 101) and the fascia boards 211 of the roof to seal off the sides of the space between the array 101-106 and the roof 100. This helps create a chimney effect for channeling hot air in the space between the array 101-106 and the roof 100. The chimney effect (also known as stack effect) is the movement of air into and out of containers (such as buildings, chimneys, flue gas stacks, etc.), and is driven by buoyancy. This buoyancy occurs due to a difference in air density resulting from temperature differences. The buoyancy force depends on the thermal difference and the height of the structure.

In one aspect of the invention, a set of temperature sensors 223 and 233 and a differential temperature controller 224 are provided for controlling a pump 225 that pumps the glycol solution through the system. For example, the differential temperature controller 224 may control the pump 225 to maintain a constant temperature differential between the sensors 223 and 233.

According to another aspect of the invention, a method for constructing a roof system is provided. The method comprises the steps of designing a structure to include a solar photovoltaic power generation system that provides a passive solar space, and partially enclosing the passive solar space to produce a chimney effect between a roof surface and the photovoltaic panels.

In one aspect, the roof system may comprise a plurality of horizontal truss members, each truss member having a length designed to cover the pre-existing structure plus a passive solar space addition; and a primary roof having a pitch and a surface area designed to accommodate the solar photovoltaic system to provide electricity.

In another aspect of the invention, a method for designing a roof system is performed by a software program residing on a computer-readable memory. The software program comprises a truss design code segment configured for calculating a roof system width designed to cover a pre-existing structure plus a passive solar space addition; and a roof surface code segment configured for calculating roof surface area and pitch sufficient to accommodate a solar photovoltaic system to provide all of the structure's electricity usage.

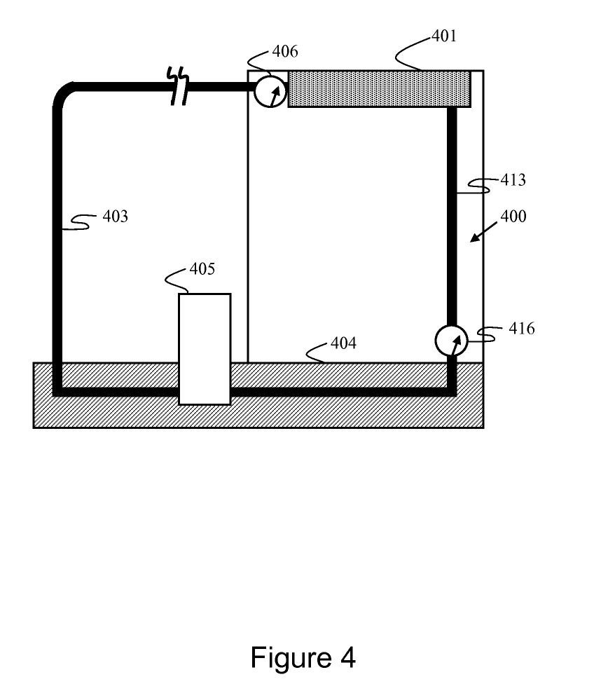

In one aspect of the invention, as shown in FIG. 4, a heat conduction collector 401 comprises a copper plate collector typically used in solar thermal flat plate collectors for collecting heat. The collector 401 is mounted on the ceiling of the passive solar space 400. Heat from the collector 401 is transferred by liquid (typically water) pumped through the conduit 413 to the thermal mass 404, which may include a concrete floor system, masonry walls, or similar structures for storing heat collected from the passive solar space 400. According to one aspect, the pump 405 is activated by a differential temperature controller (DTC) having two sensors 406 and 416. One sensor 406 is located on at least one output conduit (e.g., conduit 403) coupled to the copper plate collector 401. The other sensor 416 is located on at least one return conduit 413 that returns the liquid from the thermal mass 404 to the collector 401. The DTC automatically activates the pump 405 when the collector 401 heats up.

In yet another aspect of the invention, the PV array comprises a fin tube collector mounted along the roof and below the top of the PV array. The PV array is sealed off along its edges to cause the heat build up behind the array to chimney up through the fin tubes. The fin tube may be coupled to the liquid heat transfer loop, in which case, a mix of glycol and water may be used to transfer heat and prevent freezing.

It should be appreciated that in some aspects of the invention, an existing home or home plan may be adapted to include the building designs and energy system described herein, such as to provide a novel Hybrid/ZEB Home.

1. A solar electricity and heating system, comprising:
a photovoltaic system comprising at least one photovoltaic panel mountable above a sloped roof surface for providing photovoltaic electricity and heating a space between the at least one photovoltaic panel and the roof surface;
a heat conduction collector positioned in the space; and
a closure system mountable to at least two sides of the photovoltaic system for partially enclosing the space to provide a chimney effect.

2. The system recited in claim 1, further comprising a liquid heat transfer system comprising at least one conduit for thermally coupling the collector to at least one of a heat storage system and a heat circulation system.

3. The system recited in claim 2, further comprising a thermostat-activated pump configured for circulating liquid through the heat transfer system.
